(19) United States
(12) Patent Application Publication
(10) Pub. No.: US 2025/0357271 A1
(43) Pub. Date: Nov. 20, 2025

(54) SEMICONDUCTOR PACKAGE STRUCTURE AND MANUFACTURING METHOD THEREOF, AND MEMORY SYSTEM

(71) Applicant: YANGTZE MEMORY TECHNOLOGIES CO., LTD., Wuhan (CN)

(72) Inventors: Wenjing LIU, Wuhan (CN); Zhong ZHANG, Wuhan (CN); Zhiyao PENG, Wuhan (CN); Dongyu FAN, Wuhan (CN); Tingting GAO, Wuhan (CN); Di WANG, Wuhan (CN)

(21) Appl. No.: 18/821,658

(22) Filed: Aug. 30, 2024

(30) Foreign Application Priority Data
May 17, 2024 (CN) 2024106199949

(51) Int. Cl. H01L 23/48; H01L 23/00; H01L 23/31; H01L 25/18; H10B 80/00

(52) U.S. Cl. CPC H01L 23/481; H01L 23/3171; H01L 25/18; H01L 24/08; H01L 24/09; H01L 24/80; H01L 2224/08145; H01L 2224/09181; H10B 80/00

(57) ABSTRACT

The present application discloses a semiconductor package structure and a manufacturing method thereof, and a memory system. The semiconductor package structure includes: a stack structure including a plurality of first dies stacked sequentially along a first direction, wherein the stack structure has a first surface and a second surface opposite to each other along the first direction; and a plurality of first connection structures extending along the first direction from the second surface and respectively connected to different ones of the first dies, wherein the number of the first connection structures connected to different ones of the first dies is different, and/or maximum sizes, along a second direction, of the first connection structures connected to different ones of the first dies are different, and the first direction intersects with the second direction.

### CROSS-REFERENCE TO RELATED APPLICATIONS

The present application claims priority to Chinese Patent Application No. 2024106199949, which was filed May 17, 2024, is titled “SEMICONDUCTOR PACKAGING STRUCTURE AND PREPARATION METHOD THEREOF, STORAGE SYSTEM,” and is hereby incorporated herein by reference in its entirety.

### TECHNICAL FIELD

Implementations of the present application relate to the technical field of semiconductors, and particularly to a semiconductor package structure and a manufacturing method thereof, and a memory system.

### BACKGROUND

As the level of integrated circuits (ICs) continues to evolve, 2D-ICs can no longer meet the requirements of miniaturization, high density and low power consumption, such that 3D-ICs emerge as the times require. The high bandwidth memory (HBM) is a representative semiconductor package structure in the 3D-ICs. The HBM generally comprises a plurality of dynamic random access memory dies (DRAM Dies) and one logic die. The plurality of DRAM dies are sequentially stacked on a side of the logic die, and interconnected with the logic die through trough-silicon via (TSV) structures.

At present, how to accelerate the signal transmission speed of the semiconductor package structure is one of the technical problems urgently to be solved by those skilled in the art.

### SUMMARY

Implementations of the present application provide a semiconductor package structure and a manufacturing method thereof, and a memory system, which can solve or partially solve the above-mentioned deficiencies in the related art or other deficiencies in the related art.

A first aspect of the present application provides a semiconductor package structure, which comprises:

a stack structure comprising a plurality of first dies stacked sequentially along a first direction, wherein the stack structure has a first surface and a second surface arranged opposite to each other along the first direction; and

a plurality of first connection structures all extending along the first direction from the second surface and respectively connected to different ones of the first dies,

wherein the number of the first connection structures connected to different ones of the first dies is different, and/or maximum sizes, along a second direction, of the first connection structures connected to different ones of the first dies are different, and the first direction intersects with the second direction.

A second aspect of the present application provides a manufacturing method of a semiconductor package structure, which comprises:

forming a stack structure, wherein the stack structure comprises a plurality of first dies stacked sequentially along a first direction, and the stack structure has a first surface and a second surface arranged opposite to each other along the first direction;

forming, from the second surface, a plurality of first connection holes all extending along the first direction; and

forming first connection structures in the first connection holes, wherein a plurality of the first connection structures are respectively connected to different ones of the first dies;

wherein the number of the first connection structures connected to different ones of the first dies is different, and/or maximum sizes, along a second direction, of the first connection structures connected to different ones of the first dies are different, and the first direction intersects with the second direction.

A third aspect of the present application provides a memory system, which comprises a controller and the semiconductor package structure as described in the first aspect of the present application, wherein the controller is coupled to the semiconductor package structure and configured to control the semiconductor package structure to store data.

It is to be understood that the contents as described in this part is neither intended to identify critical or important features of examples of the present application, nor used to limit the scope of the present application. Other features of the present application will become easy to be understood through the following description.

### BRIEF DESCRIPTION OF THE DRAWINGS

Other features, objectives and advantages of the present application will become more apparent by reading the detailed description of non-limitative examples made by reference to the following drawings. The drawings are used to better understand the solution, but do not constitute limitations on the present application. In the drawings:

FIG. 1 is a schematic cross-sectional view of an HBM according to an implementation of the present application;

FIGS. 2 to 11 are schematic process diagrams of a manufacturing method of a semiconductor package structure according to an implementation of the present application;

FIG. 12 is a schematic cross-sectional view of a semiconductor package structure according to one of implementations of the present application;

FIG. 13 is a schematic cross-sectional view of a semiconductor package structure according to another implementation of the present application;

FIG. 14 is a flow chart of a manufacturing method of a semiconductor package structure according to an implementation of the present application; and

FIG. 15 is a block diagram of a system having a semiconductor package structure according to an implementation of the present application.

### REFERENCE NUMERALS

100. Stack structure; 101. First surface; 102. Second surface;

103. First connection hole; 110. First die; 111. DRAM die;

111-1. First DRAM die; 111-2. Second DRAM die;

111-3. Third DRAM die; 111-4. Fourth DRAM die;

120. First connection structure; 121. First conductive structure; 122. First isolation layer;

123. First pore; 130. First joining layer; 131. First dielectric layer;

132. First joining contact; 200. Second die; 201. Logic die;

210. Second connection structure; 211. Second conductive structure; 212. Second isolation layer;

220. Second joining layer; 221. Second dielectric layer; 222. Second joining contact;

230. Third joining layer; 231. Third dielectric layer; 232. Third joining contact;

300. Substrate; 310. Fourth joining layer; 311. Fourth dielectric layer;

312. Fourth joining contact; 400. Solder ball; 500. TSV structure;

501. First TSV structure; 502. Second TSV structure;

503. Third TSV structure; 600. System; 601. Memory system;

602. Semiconductor package structure; 603. Memory controller; 604. Host.

### DETAILED DESCRIPTION

In order to better understand the present application, various aspects of the present application will be described in more detail with reference to the drawings. It is understood that these detailed descriptions are only descriptions of exemplary implementations of the present application, and are not intended to limit the scope of the present application in any manner. Like reference numbers refer to like elements throughout the specification. The expression “and/or” includes any or all combinations of one or more of listed associated items.

It is to be noted that, in the specification, the expressions, such as first, second, third and the like, are only used to distinguish one feature from another feature, instead of representing any limitation to the features, particularly instead of representing any sequential order.

For case of illustration, the thicknesses, sizes and shapes of components have been slightly adjusted in the drawings. The drawings are merely exemplary and are not drawn to scale precisely. As used herein, terms, “approximately”, “about”, and the like, are used to represent approximation, instead of representing a degree, and are intended to describe inherent deviations in measured values or calculated values as recognized by those of ordinary skill in the art.

It should be also understood that expressions, such as “comprise”, “comprising”, “have”, “include”, and/or “including”, etc., are open-ended expressions, rather than close-ended expressions in the specification. They represent the existence of the stated features, elements and/or components, but the existence of one or more other features, elements, components and/or combinations thereof is not precluded. Moreover, the expression, such as “at least one of . . . ”, appearing before a list of listed features, modifies the whole list of features, rather than an individual element therein. Furthermore, “may” is used to represent “one or more implementations of the present application” when describing the implementations of the present application. Moreover, the term “exemplary” is intended to refer to an example or illustration.

Unless otherwise defined, all phrases (including engineering terms and technical terms) used herein have the same meanings as those generally understood by those of ordinary skill in the art to which the present application pertains. It should be further understood that words as defined in common dictionaries should be interpreted as having a meaning that is consistent with their meaning in the context of the related art, and should not be interpreted in an idealized or overly formal sense unless otherwise stated expressly in the present application.

It is to be noted that examples and features in the examples of the present application may be joined with each other in the case of no conflicts. In addition, unless otherwise defined expressly or conflicting with the context, specific operations included in a method set forth in the present application are not necessarily limited to the described order, but may be carried out in any order or in parallel. The present application will now be described below in detail with reference to the drawings and in conjunction with the examples.

Furthermore, in the present application, the term “layer” refers to a material portion including a region with a thickness. A layer may extend over the entirety of an underlying or overlying structure or may have an extent less than the extent of an underlying or overlying structure. Furthermore, a layer may be a region of a homogeneous or inhomogeneous continuous structure that has a thickness less than the thickness of the continuous structure. A layer may extend horizontally, vertically, and/or along a tapered surface. A layer may include multiple sub-layers. In addition, “connected” or “joined”, when used in the present application, may represent direct contact or indirect contact between respective components, unless otherwise expressly defined or derived from the context.

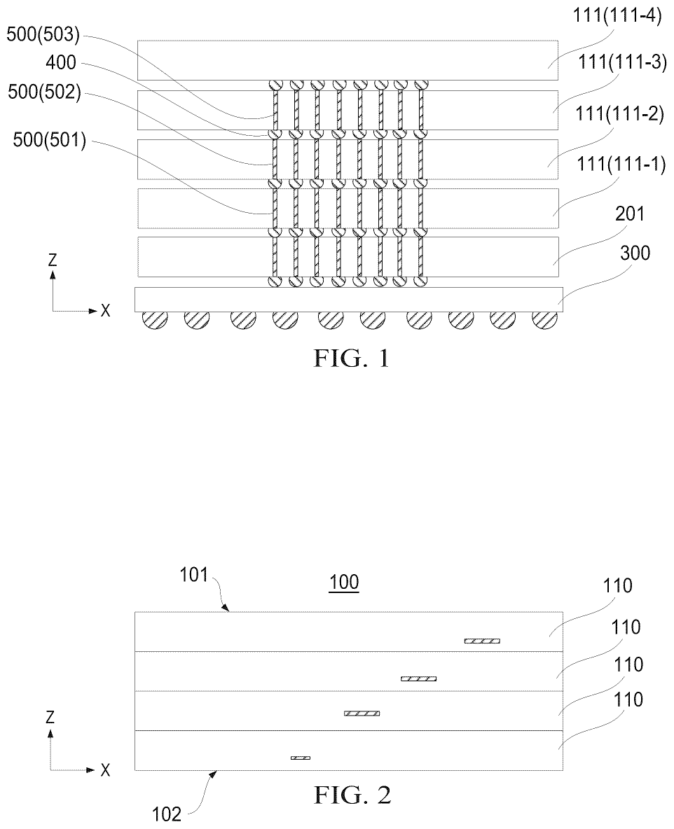

As shown in FIG. 1, a high bandwidth memory (HBM) generally comprises a substrate 300, a logic die 201, and a plurality of dynamic random access memory dies (DRAM Dies) 111, wherein the logic die 201 is located on a side of the substrate 300, the plurality of DRAM dies 111 are sequentially stacked on a side of the logic die 201 away from the substrate 300 along a first direction (z direction), a trough-silicon via (TSV) structure is formed in the DRAM die 111, which is close to the logic die 201 in two adjacent DRAM dies 111, and two adjacent TSV structures 500 are connected through solder balls 400. Therefore, the DRAM die 111 can be connected with the logic die 201 through at least one of: at least one TSV structure 500 or the solder balls 400.

Using the HBM shown in FIG. 1 as an example, four DRAM dies 111 are sequentially stacked on a side of the logic die 201 along the first direction (z direction). For ease of description, the four DRAM dies 111 may be sequentially referred to as a first DRAM die 111-1, a second DRAM die 111-2, a third DRAM die 111-3, and a fourth DRAM die 111-4 along a direction away from the logic die 201. A first TSV structure 501 extending through the first DRAM die 111-1 along the first direction (z direction) is formed in the first DRAM die 111-1, a second TSV structure 502 extending through the second DRAM die 111-2 along the first direction (z direction) is formed in the second DRAM die 111-2, and a third TSV structure 503 extending through the third DRAM die 111-3 along the first direction (z direction) is formed in the third DRAM die 111-3. The fourth DRAM die 111-4 is connected to the logic die 201 through the third TSV structure 503, the second TSV structure 502, the first TSV structure 501 and the plurality of solder balls 400, the third DRAM die 111-3 is connected to the logic die 201 through the second TSV structure 502, the first TSV structure 501 and the plurality of solder balls 400, the second DRAM die 111-2 is connected to the logic die 201 through the first TSV structure 501 and the plurality of solder balls 400, and the first DRAM die 111-1 may be directly connected to the logic die 201 through the solder balls 400 without the help of the TSV structure 500. It can be seen that a distance of the DRAM die 111 from the logic die 201 along the first direction is farther, a signal transmission path between the DRAM die 111 and the logic die 201 is longer, an overall length, along the first direction (z direction), of the TSV structures 500 required between the DRAM die 111 and the logic die 201 is longer, resistance is greater, and thus a signal transmission speed is slower.

Based on this, in order to solve at least part of the above-mentioned problems, implementations of the present application provide a semiconductor package structure. FIG. 5 shows a schematic cross-sectional view of a semiconductor package structure according to one of implementations of the present application. As shown in FIG. 5, the semiconductor package structure comprises a stack structure 100 and a plurality of first connection structures 120, wherein the stack structure 100 has a first surface 101 and a second surface 102 arranged opposite to each other along the first direction (z direction), and the first connection structures 120 extends into the stack structure 100 along the first direction (z direction) from the second surface 102 of the stack structure 100.

The stack structure 100 comprises a plurality of first dies 110 sequentially stacked along the first direction (z direction), and the plurality of first connection structures 120 all extend along the first direction (z direction) from the second surface 102 of the stack structure 100 and are connected to different first dies 110. The number of the first connection structures 120 connected to different first dies 110 is different, and/or maximum sizes, along a second direction (x direction), of the first connection structures 120 connected to different first dies 110 are different, and the first direction intersects with the second direction.

It is to be noted that, “the first direction intersects with the second direction” described above may generally be understood that there is an included angle between the first direction and the second direction, for example, the first direction and the second direction are perpendicular or approximately perpendicular to each other. As an example, as shown in FIG. 5, in an implementation of the present application, the first direction may be a thickness direction of the first die 110, i.e., the z direction, and the second direction may be a width or length direction of the first die 110, i.e., the x direction or a y direction. Furthermore, the semiconductor package structure provided by the implementations of the present application may be a memory, or may also be a portion of the memory.

Therefore, as shown in FIGS. 11 to 13, if the stack structure 100 is subsequently connected to other structures such as the logic die or the substrate 300 or the like, at least one of the number of the first connection structures 120 connected to the first dies 110 or the maximum sizes of the first connection structures 120 along the second direction (x direction) may be set according to distances of various first dies 110 relative to other structures, such that the number of the first connection structures 120 connected to different first dies 110 is different, and/or the maximum sizes, along the second direction (x direction), of the first connection structures 120 connected to different first dies 110 are different. Since at least one of the number of the first connection structures 120 connected to the same first die 110 or the maximum sizes of the first connection structures 120 along the second direction (x direction) may affect overall equivalent resistance of all the first connection structures 120 connected to the first die 110, in the present application, by causing at least one of the number of the first connection structures 120 connected to different first dies 110 or the maximum sizes of the first connection structures 120 along the second direction (x direction) to be different, resistance differences between different first connection structures 120 due to the fact that distances of the first dies 110 from other structures such as the logic die or the substrate 300 or the like are different (i.e., extending lengths of the first connection structures 120 along the first direction (z direction) are different) can be compensated, such that an overall signal transmission speed of the first connection structures 120 connected to the farther first dies 110 can be improved.

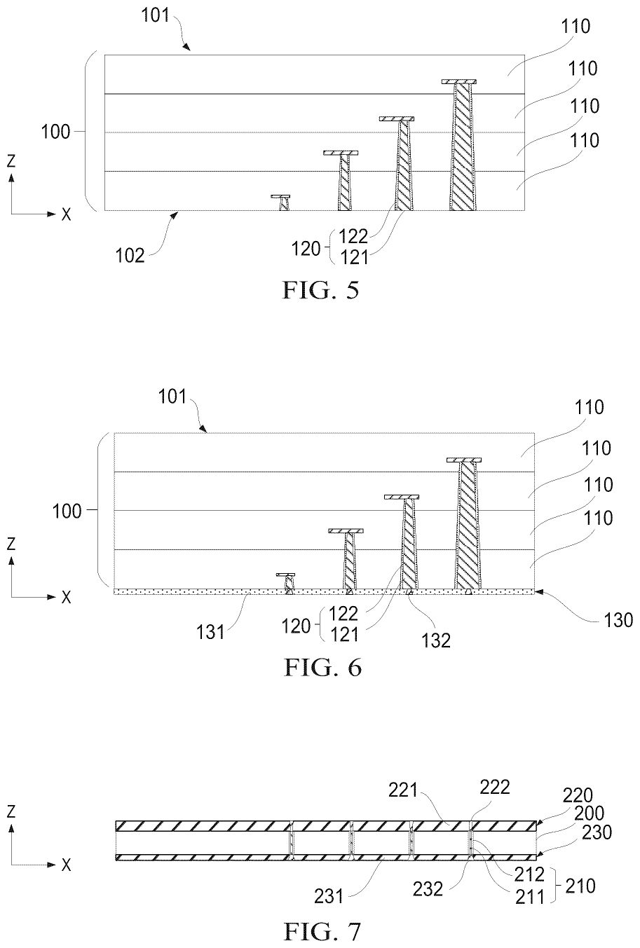

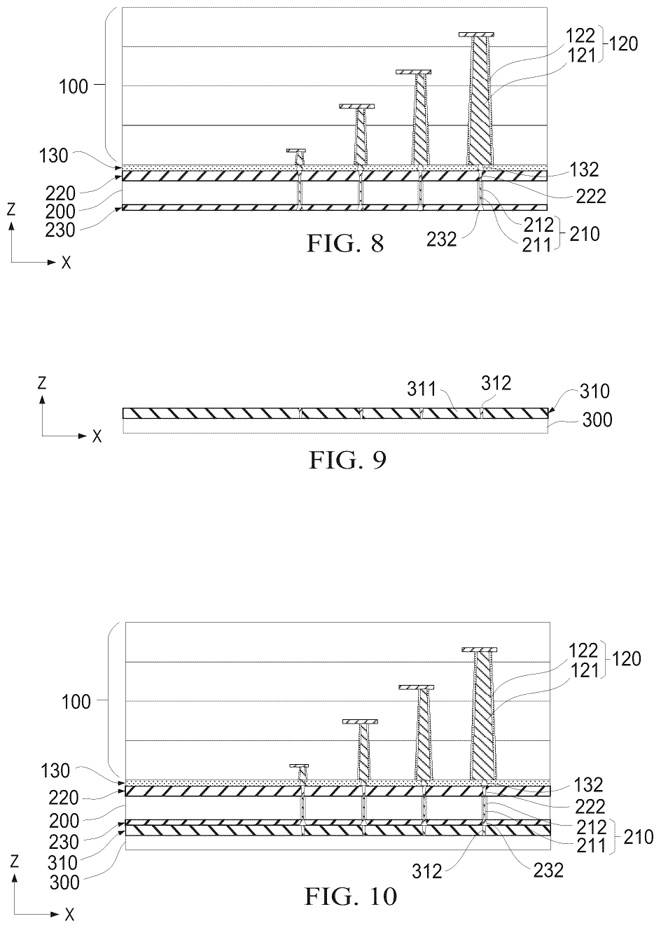

As an example, as shown in FIG. 12, the number of the first connection structures 120 connected to one of two adjacent first dies 110 is greater than the number of the first connection structures 120 connected to the other one of the two first dies 110; as shown in FIG. 11, a maximum size, along the second direction (x direction), of the first connection structures 120 connected to one of the first dies 110 is greater than a maximum size, along the second direction (x direction), of the first connection structures 120 connected to another one of the first dies 110; as shown in FIG. 13, the number of the first connection structures 120 connected to one of two adjacent first dies 110 is greater than the number of the first connection structures 120 connected to the other one of the two first dies 110, and the maximum sizes, along the second direction (x direction), of the first connection structures 120 connected to one of the first dies 110 are greater than the maximum sizes, along the second direction (x direction), of the first connection structures 120 connected to another one of the first dies 110. The one of the first dies 110 is located on a side of the another one of the first dies 110 along a direction from the second surface 102 to the first surface 101.

For ease of description, in the following, one of two adjacent first dies 110 is referred to as a first stack die, and the other one is referred to as a second stack die, wherein the first stack die is located on a side of the second stack die along the direction from the second surface 102 to the first surface 101 of the stack structure 100. It is to be noted that, introducing the first stack die and the second stack die in the present application is only to conveniently distinguish relative positions of two adjacent first dies 110 along the first direction (z direction), the first stack die or the second stack die does not fixedly refer to a particular first die 110. Using the semiconductor package structure shown in FIG. 5 as an example, the stack structure 100 of the semiconductor package structure comprises four first dies 110, an upper surface of the stack structure 100 is the first surface 101, and a lower surface of the stack structure 100 is the second surface 102. For the uppermost two first dies 110, i.e., the first die 110 located at a fourth layer and the first die 110 located at a third layer, the first die 110 located at the fourth layer may be referred to as the first stack die, and the first die 110 located at the third layer may be referred to as the second stack die. For the middle two first dies 110, i.e., the first die 110 located at the third layer and the first die 110 located at a second layer, the first die 110 located at the third layer may be referred to as the first stack die, and the first die 110 located at the second layer may be referred to as the second stack die.

According to the above, the first stack die is located on a side of the second stack die along the direction from the second surface 102 to the first surface 101 of the stack structure 100. In other words, the first stack die is farther away from other structures such as the logic die or the substrate 300 or the like than the second stack die, such that an extending length, along the first direction (z direction), of the first connection structure 120 connected to the first stack die is greater than an extending length, along the first direction (z direction), of the first connection structure 120 connected to the second stack die, and the extending length of the first connection structure 120 along the first direction (z direction) is longer, the resistance is greater, and the signal transmission speed is slower. As shown in FIG. 12, in some implementations, in order to improve the overall signal transmission speed of the first connection structures 120 connected to the first stack die, the number of the first connection structures 120 connected to the first stack die is greater than the number of the first connection structures 120 connected to the second stack die. For the plurality of first connection structures 120 connected to the same first die 110, one end of each of these first connection structures 120 is connected to the first die 110, and the other end extends through the second surface 102 of the stack structure 100 along the first direction (z direction), and is connected to other structures such as the logic die or the substrate 300 or the like, such that the plurality of first connection structures 120 connected to the same first die 110 are in a parallel relationship with each other, and as the number of the first connection structures 120 connected in parallel increases, the overall equivalent resistance of these first connection structures 120 is reduced. Based on this, in the implementations of the present application, by increasing the number of the first connection structures 120 connected to the first stack die, the number of the first connection structures 120 connected to the first stack die is greater than the number of the first connection structures 120 connected to the second stack die, such that a signal transmission width may be increased, and the overall equivalent resistance of all the first connection structures 120 connected to the first stack die may also be reduced, thereby improving the overall signal transmission speed of the first connection structures 120 connected to the first stack die, so as to cause a signal transmission speed between the first stack die and such as the logic die and a signal transmission speed between the second stack die and such as the logic die to be approximately the same.

As shown in FIG. 11, in some other implementations, in order to improve the overall signal transmission speed of the first connection structure 120 connected to the first stack die, the maximum size, along the second direction (x direction), of the first connection structures 120 connected to the first stack die is greater than the maximum size, along the second direction (x direction), of the first connection structures 120 connected to the second stack die. Since the resistance of the first connection structure 120 is inversely proportional to the size of the first connection structure 120 along the second direction (x direction), in the implementations of the present application, by increasing the maximum sizes, along the second direction (x direction), of the first connection structures 120 connected to the first stack die, the resistance of the first connection structures 120 connected to the first stack die may be reduced, such that the overall signal transmission speed of the first connection structures 120 connected to the first stack die is improved, thereby causing the signal transmission speed between the first stack die and such as the logic die 201 and the signal transmission speed between the second stack die and such as the logic die 201 to be approximately the same. It is to be noted that, along the first direction (z direction), the size of the first connection structure 120 in the second direction (x direction) may be the same, and in this case, the maximum size of the first connection structure 120 in the second direction (x direction) is an average size of the first connection structure 120 in the second direction (x direction). However, due to limitations of a current etching process, in the direction from the second surface 102 to the first surface 101 of the stack structure 100, the size of the first connection structure 120 in the second direction (x direction) may gradually reduce. In this case, the maximum size of the first connection structure 120 in the second direction (x direction) is greater than the average size of the first connection structure 120 in the second direction (x direction).

As shown in FIG. 13, in some other implementations, the number of the first connection structures 120 connected to the first stack die and the sizes of the first connection structures 120 along the second direction (x direction) may be increased at the same time, such that the number of the first connection structures 120 connected to the first stack die is greater than the number of the first connection structures 120 connected to the second stack die, and at the same time, the maximum size, along the second direction (x direction), of the first connection structures 120 connected to the first stack die is greater than the maximum size, along the second direction (x direction), of the first connection structures 120 connected to the second stack die.

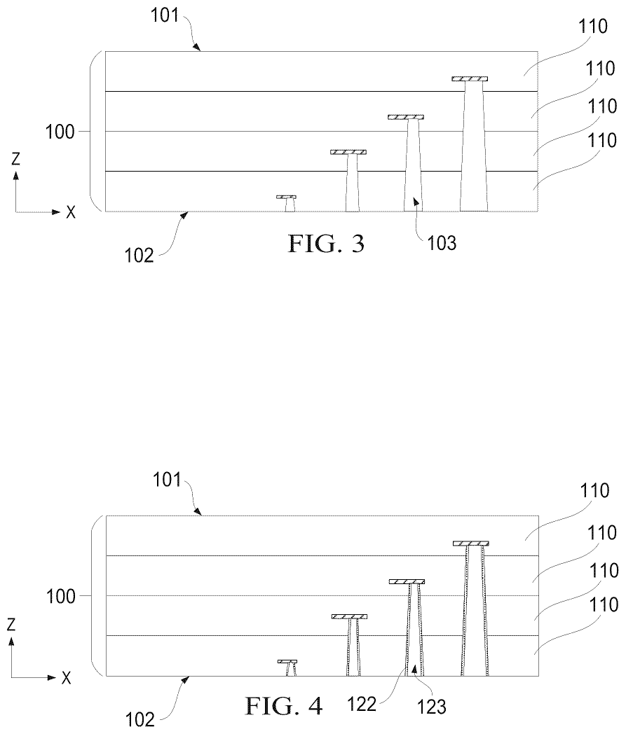

As described above, two adjacent TSV structures 500 in FIG. 1 are connected through the solder balls 400, due to limitations of formation process of the solder balls 400, a size of the solder ball 400 along the first direction (z direction) is relatively large, and a dielectric material is also filled around the solder ball 400, i.e., between two adjacent DRAM dies 111, this results in that not only is a spacing between two adjacent TSV structures 500 increased, such that resistance between two adjacent TSV structures 500 is increased, the signal transmission speed is reduced, but also a thickness of the entire semiconductor package structure along the first direction (z direction) is increased. Therefore, as shown in FIG. 2, in order to reduce the thickness of the entire semiconductor package structure along the first direction (z direction) and further improve the signal transmission speed, in the implementations of the present application, two adjacent first dies 110 are connected through bonding. Two adjacent first dies 110 may be connected through bonding such as direct bonding or adhesive bonding or the like, but not limited thereto.

In some implementations, as shown in FIG. 5, the first connection structure 120 comprises a first conductive structure 121 and a first isolation layer 122, the first conductive structure 121 extends along the first direction (z direction) from the second surface 102 of the stack structure 100 and is connected to the corresponding first die 110, and the first isolation layer 122 clads a sidewall of the first conductive structure 121 extending along the first direction (z direction). A material of the first conductive structure 121 may include, but is not limited to, at least one of metal such as tungsten, copper, gold, aluminum, chromium, tin, nickel, titanium, zinc, etc., metallic alloy such as tin lead alloy, etc., and metal silicide, and a material of the first isolation layer 122 may include, but is not limited to, silicon oxide, silicon oxynitride, or silicon nitride. It is to be noted that, one end of the first connection structure 120 extends through the second surface 102 of the stack structure 100, and the other end may extend to a surface of the corresponding first die 110 or extend inside the corresponding first die 110. As an example, as shown in FIG. 5, the plurality of first connection structures 120 respectively extend into different first dies 110 along the first direction (z direction).

In some implementations, as shown in FIGS. 6 and 8, the semiconductor package structure may further comprise a second die 200 and a plurality of second connection structures 210, wherein the second die 200 is located on a side of the stack structure 100 along a direction from the first surface 101 to the second surface 102 of the stack structure 100, the second connection structures 210 extends through the second die 200 along the first direction (z direction), and the plurality of second connection structures 210 are respectively connected to different first connection structures 120. As an example, as shown in FIG. 7, the second connection structure 210 comprises a second conductive structure 211 and a second isolation layer 212, wherein the second conductive structure 211 extends through the second die 200 along the first direction (z direction), and the second isolation layer 212 clads a sidewall of the second conductive structure 211 extending along the first direction (z direction). A material of the second conductive structure 211 may include, but is not limited to, at least one of metal, metallic alloy and metal silicide, and a material of the second isolation layer 212 may include, but is not limited to, silicon oxide, silicon oxynitride, or silicon nitride.

It is to be noted that, types of the plurality of first dies 110 may be the same or different. The first die 110 may comprise at least one of a memory die or a peripheral circuit, the memory die is mainly configured to store data, the memory die may be a non-volatile die such as a NAND die, a programmable read-only memory (PROM) die, or a NOR die, etc., or may also be a volatile die such as a dynamic random access memory (DRAM) die, a static random-access memory (SRAM) die, etc., and the peripheral circuit may include, but is not limited to, at least one of a high voltage device, a low voltage device and an ultra-low voltage device. The high voltage device may include, but is not limited to, at least one of a row decoder, a column decoder, a word line driver and a bit line driver, the low voltage device may include, but is not limited to, a page buffer or a logic device, and the ultra-low voltage device may include, but is not limited to, an input/output (I/O) circuit. The second die 200 may comprise a logic die which is mainly configured to perform tasks such as digital logic operation, execution logic control, decision designation, signal processing, etc., the logic die may comprise at least one of a central processing unit (CPU), a digital signal processor (DSP), a field programmable gate array (FPGA), an application specific integrated circuit (ASIC), a security die, an interface die, or a memory control die.

In some examples, as shown in FIG. 12, the number of the first connection structures 120 connected to different first dies 110 gradually increases, and in two adjacent first dies 110, the number of the first connection structures 120 connected to the first die 110 away from the second die 200 is greater than the number of the first connection structures 120 connected to the first die 110 close to the second die 200. Using the semiconductor package structure shown in FIG. 12 as an example, the stack structure 100 of the semiconductor package structure comprises four first dies 110 and ten first connection structures 120, wherein one of the first connection structures 120 is connected to the lowest first die 110, i.e., the first die 110 located at a first layer, two first connection structures 120 are connected to the first die 110 located at the second layer, three first connection structures 120 are connected to the first die 110 located at the third layer, and four first connection structures 120 are connected to the uppermost first die 110, i.e., the first die 110 located at the fourth layer. Similarly, the sizes, along the second direction (x direction), of the first connection structures 120 connected to different first dies 110 gradually increase, and in two adjacent first dies 110, the maximum size, along the second direction (x direction), of the first connection structures 120 connected to the first die 110 away from the second die 200 is greater than the maximum size, along the second direction (x direction), of the first connection structures 120 connected to the first die 110 close to the second die 200.

In some implementations, as shown in FIGS. 6 to 8, in the implementations of the present application, a side of the stack structure 100 facing toward the second die 200 is provided with a first joining layer 130, a side of the second die 200 facing toward the stack structure 100 is provided with a second joining layer 220, the first joining layer 130 is connected to the first connection structure 120, the second joining layer 220 is connected to the second connection structure 210, and the first joining layer 130 is joined to the second joining layer 220. For example, as shown in FIGS. 5 and 6, after the stack structure 100 is formed, the first joining layer 130 may be formed on the second surface 102 of the stack structure 100. As shown in FIG. 7, after the second die 200 is formed, the second joining layer 220 may be formed on a side of the second die 200. Then, as shown in FIG. 8, the first joining layer 130 and the second joining layer 220 are bonded together. At least one of the first joining layer 130 or the second joining layer 220 may be a single-layer structure, or may also be a multilayer structure. The first joining layer and the second joining layer may have a same structure or different structures, and are not limited thereto in the present application.

As an example, the second die 200 and the stack structure 100 are connected through bonding. The second die 200 and the stack structure 100 may be connected through bonding such as direct bonding, adhesive bonding, hybrid bonding, etc., but not limited thereto. For example, the second die 200 and the stack structure 100 are connected through hybrid bonding, both the first joining layer 130 and the second joining layer 220 are bonding layers. As shown in FIG. 6, the first joining layer 130 may comprise a first dielectric layer 131 and a plurality of first joining contacts 132, the first joining contacts 132 extend through the first dielectric layer 131 along the first direction (z direction), and the plurality of first joining contacts 132 are respectively connected to different first connection structures 120. As an example, the first joining contacts 132 and the first connection structures 120 may be correspondingly arranged one to one, in other words, the number of the first joining contacts 132 is the same as the number of the first connection structures 120, one end of the first joining contact 132 is in contact with the corresponding first connection structure, and the other end extends through the first dielectric layer 131 along the first direction (z direction). A material of the first joining contact 132 may include, but is not limited to, at least one of metal, metallic alloy and metal silicide. As shown in FIG. 7, the second joining layer 220 may comprise a second dielectric layer 221 and a plurality of second joining contacts 222, the second joining contacts 222 extend through the second dielectric layer 221 along the first direction (z direction), and the plurality of second joining contacts 222 are respectively connected to different second connection structures 210. As an example, the second joining contacts 222 and the second connection structures 210 may be correspondingly arranged one to one, one end of the second joining contact 222 is in contact with the corresponding second connection structure, and the other end extends through the second dielectric layer 221 along the first direction (z direction). A material of the second joining contact 222 may include, but is not limited to, at least one of metal, metallic alloy and metal silicide. In conjunction with FIGS. 6 to 8, the first joining layer 130 is bonded to the second joining layer 220, the first dielectric layer 131 is at least in partial contact with the second dielectric layer 221, and the plurality of first joining contacts 132 are respectively in contact with different second joining contacts 222. Furthermore, using the first joining contact 132 as an example, when the first joining contact 132 is a contact comprising a metal element, in order to avoid diffusion of metal particles of the first joining contact 132 to the stack structure 100, i.e., the first die 110, the first joining layer 130 may further comprise a first blocking layer (not shown), wherein the first blocking layer is located between the first dielectric layer 131 and the stack structure 100, and the first joining contact 132 extends through the first dielectric layer 131 and the first blocking layer sequentially along the first direction (z direction). Similarly, the second joining layer 220 may further comprise a second blocking layer (not shown), wherein the second blocking layer is located between the second dielectric layer 221 and the second die 200, and the second joining contact 222 extends through the second dielectric layer 221 and the second blocking layer sequentially along the first direction (z direction). Materials of the first blocking layer and the second blocking layer may include, but are not limited to, at least one of silicon nitride or doped silicon nitride.

In some implementations, as shown in FIG. 10, the semiconductor package structure may further comprise a substrate 300 located on a side of the second die 200 away from the stack structure 100, the substrate 300 is connected to the second connection structure 210. As shown in FIGS. 8 to 10, a side of the second die 200 away from the stack structure 100 is provided with a third joining layer 230, a side of the substrate 300 facing toward the second die 200 is provided with a fourth joining layer 310, the third joining layer 230 is connected to the second connection structure 210, the fourth joining layer 310 is connected to the substrate 300, and the third joining layer 230 is joined with the fourth joining layer 310. For example, as shown in FIG. 7, after the second die 200 is formed, the third joining layer 230 may be formed on a side of the second die 200. Furthermore, as shown in FIG. 9, the fourth joining layer 310 may be formed on a side of the substrate 300. Then, as shown in FIG. 10, the third joining layer 230 and the fourth joining layer 310 are joined together. At least one of the third joining layer 230 or the fourth joining layer 310 may be a single-layer structure, or may also be a multilayer structure. The third joining layer and the fourth joining layer may have a same structure or different structures, and the present application is not limited thereto. When the semiconductor package structure comprises the second joining layer 220 and the third joining layer 230, the second joining layer 220 and the third joining layer 230 are respectively located on two sides of the second die 200 along the first direction (z direction). The second joining layer 220 may be first formed on one side of the second die 200, then the third joining layer 230 is formed on the other side of the second die 200; or the third joining layer 230 may be first formed on one side of the second die 200, then the second joining layer 220 is formed on the other side of the second die 200, and the present application is not limited thereto.

As an example, the second die 200 and the substrate 300 are connected through bonding. The second die 200 and the substrate 300 may be connected through bonding such as direct bonding, adhesive bonding, hybrid bonding, etc., but not limited thereto. For example, the second die 200 and the substrate 300 are connected through hybrid bonding, and both the third joining layer 230 and the fourth joining layer 310 are joining layers. As shown in FIG. 7, the third joining layer 230 may comprise a third dielectric layer 231 and a plurality of third joining contacts 232, the third joining contacts 232 extend through the third dielectric layer 231 along the first direction (z direction), and the plurality of third joining contacts 232 are respectively connected to different second connection structures 210. As an example, the third joining contacts 232 and the second connection structures 210 may be correspondingly arranged one to one, in other words, the number of the third joining contacts 232 is the same as the number of the second connection structures 210, one end of the third joining contact 232 is in contact with the second connection structure 210, and the other end extends the third dielectric layer 231 along the first direction (z direction). As shown in FIG. 9, the fourth joining layer 310 may comprise a fourth dielectric layer 311 and a plurality of fourth joining contacts 312, the fourth joining contacts 312 extend through the fourth dielectric layer 311 along the first direction (z direction), and are connected to the substrate 300. A material of at least one of the third joining contact 232 or the fourth joining contact 312 may include, but is not limited to, at least one of metal, metallic alloy and metal silicide. In conjunction with FIGS. 8 to 10, the third joining layer 230 is bonded to the fourth joining layer 310, the third dielectric layer 231 is at least in partial contact with the fourth dielectric layer 311, and the plurality of third joining contacts 232 are respectively in contact with different fourth joining contacts 312. Furthermore, using the third joining contact 232 as an example, when the third joining contact 232 is a contact comprising a metal element, in order to avoid diffusion of metal particles of the third joining contact 232 to the second die 200, the third joining layer 230 may further comprise a third blocking layer (not shown), wherein the third blocking layer is located between the third dielectric layer 231 and the second die 200, and the third joining contact 232 extends through the third dielectric layer 231 and the third blocking layer sequentially along the first direction (z direction), and is connected to the corresponding second connection structure 210. Similarly, the fourth joining layer 310 may further comprise a fourth blocking layer (not shown), wherein the fourth blocking layer is located between the fourth dielectric layer 311 and the substrate 300, and the fourth joining contact 312 extends through the fourth dielectric layer 311 and the fourth blocking layer sequentially along the first direction (z direction), and is connected to the substrate 300. Materials of the third blocking layer and the fourth blocking layer may include, but are not limited to, at least one of silicon nitride or doped silicon nitride.

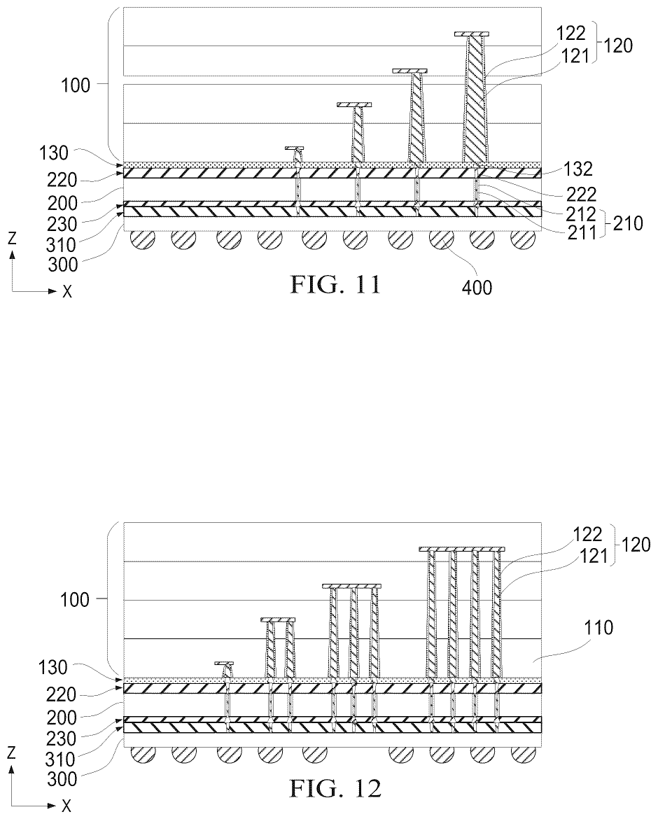

Furthermore, as shown in FIG. 14, an implementation of the present application further provide a manufacturing method of a semiconductor package structure. The manufacturing method 1000 comprises:

S100, forming a stack structure 100, wherein the stack structure 100 comprises a plurality of first dies 110 stacked sequentially along a first direction (z direction), and the stack structure 100 has a first surface 101 and a second surface 102 (referring to FIG. 2) arranged opposite to each other along the first direction (z direction);

S200, forming, from the second surface 102 of the stack structure 100, a plurality of first connection holes 103 (referring to FIG. 3) all extending along the first direction (z direction), wherein the plurality of first connection holes 103 may extend to surfaces of different first dies 110 from the second surface 102, or may also extend into different first dies 110 from the first surface 101; and

S300, forming first connection structures 120 in the first connection holes 103, the plurality of first connection structures 120 are respectively connected to different first dies 110 (referring to FIG. 5).

As shown in FIGS. 11 to 13, the number of the first connection structures 120 connected to different first dies 110 is different, and/or maximum sizes, along a second direction (x direction), of the first connection structures 120 connected to different first dies 110 are different, and the first direction intersects with the second direction.

If the stack structure 100 is subsequently connected to other structures such as the logic die 201 or the substrate 300 or the like, when the first connection holes 103 are formed, at least one of the number of the first connection holes 103 corresponding to different first dies 110 or maximum sizes of the first connection holes 103 along the second direction (x direction) may be set according to distances of various first dies 110 relative to other structures, such that the number of the first connection structures 120 connected to different first dies 110 is different, and/or the maximum sizes, along the second direction (x direction), of the first connection structures 120 connected to different first dies 110 are different. Since at least one of the number of the first connection structures 120 connected to the same first die 110 or the maximum sizes of the first connection structures 120 along the second direction (x direction) may affect overall equivalent resistance of all the first connection structures 120 connected to the first die 110, in the implementations of the present application, by causing at least one of the number of the first connection structures 120 connected to different first dies 110 or the maximum sizes of the first connection structures 120 along the second direction (x direction) to be different, resistance differences between different first connection structures 120 due to the fact that distances of the first dies 110 from other structures such as the logic die 201 or the substrate 300 or the like are different (i.e., extending lengths of the first connection structures 120 along the first direction (z direction) are different) can be compensated, such that an overall signal transmission speed of the first connection structures 120 connected to the farther first dies 110 can be improved.

In some implementations, as shown in FIG. 2, the stack structure 100 may be formed by the following manner: the plurality of first dies 110 are sequentially connected through bonding along the first direction (z direction). Two adjacent first dies 110 are connected through bonding such as direct bonding or adhesive bonding or the like, but not limited thereto.

In some implementations, as shown in FIG. 5, the first connection structure 120 comprises a first isolation layer 122 and a first conductive structure 121, thus the first connection structure 120 may be formed in the first connection hole 103 by the following manners: as shown in FIG. 4, the first isolation layer 122 is formed on a sidewall of the first connection hole 103 extending along the first direction (z direction), wherein a material of the first isolation layer 122 may include, but is not limited to, silicon oxide, silicon oxynitride, or silicon nitride; and as shown in FIGS. 4 and 5, the first conductive structure 121 is formed in a first pore 123 surrounded by the first isolation layer 122, wherein a material of the first conductive structure 121 may include, but is not limited to, at least one of metal such as tungsten, copper, gold, aluminum, chromium, tin, nickel, titanium, zinc, etc., metallic alloy such as tin lead alloy, etc., and metal silicide. In an implementation of the present application, both the first isolation layer 122 and the first conductive structure 121 may formed in the first connection hole 103 through a thin film deposition process, and the thin film deposition process may be, but not limited to, a physical vapor deposition (PVD) process, a chemical vapor deposition (CVD) process, an atomic layer deposition (ALD) process, or a combination of any of the above-mentioned processes.

In some implementations, the manufacturing method may further comprise: as shown in FIG. 7, forming a plurality of second connection structures 210 in a second die 200, the second connection structures 210 extends through the second die 200 along the first direction (z direction); and as shown in FIG. 8, joining the second die 200 with the stack structure 100. For example, as shown in FIGS. 5 and 6, a first dielectric layer 131 is formed on the second surface 102 of the stack structure 100, a plurality of first joining contacts 132 are formed in the first dielectric layer 131, the first joining contacts 132 extend through the first dielectric layer 131 along the first direction (z direction), and the plurality of first joining contacts 132 are respectively connected to different first connection structures 120; as shown in FIG. 7, a second dielectric layer 221 is formed on a side of the second die 200, a plurality of second joining contacts 222 are formed in the second dielectric layer 221, the second joining contacts 222 extend through the second dielectric layer 221 along the first direction (z direction), and the plurality of second joining contacts 222 are respectively connected to different second connection structures 210; and as shown in FIG. 8, the first dielectric layer 131 is joined with the second dielectric layer 221, and the plurality of first joining contacts 132 are respectively in contact with different second joining contacts 222. Therefore, the second surface 102 of the stack structure 100 faces toward the second die 200, and the first connection structure 120 is connected to the corresponding second connection structure 210 sequentially through the corresponding first joining contact 132 and second joining contact 222. The first dielectric layer 131 may be formed on a side of the stack structure 100 through the thin film deposition process, and the second dielectric layer 221 may also be formed on a side of the second die 200 through the thin film deposition process.

In some implementations, as shown in FIG. 10, the manufacturing method may further comprise: joining the substrate 300 with the second die 200. For example, as shown in FIG. 7, a third dielectric layer 231 is formed on a side of the second die 200, a plurality of third joining contacts 232 are formed in the third dielectric layer 231, the third joining contacts 232 all extends through the third dielectric layer 231 along the first direction (z direction) and are respectively connected to different second connection structures 210; as shown in FIG. 9, a fourth dielectric layer 311 is formed on a side of the substrate 300, a plurality of fourth joining contacts 312 are formed in the fourth dielectric layer 311, the plurality of fourth joining contacts 312 all extend through the fourth dielectric layer 311 along the first direction (z direction) and are connected to the substrate 300; and as shown in FIG. 10, the third dielectric layer 231 is joined with the fourth dielectric layer 311, and the plurality of third joining contacts 232 are respectively in contact with different fourth joining contacts 312. Therefore, the substrate 300 and the stack structure 100 are respectively located on two sides of the second die 200 along the first direction (z direction), and the second connection structure 210 is connected to the substrate 300 sequentially through the corresponding third joining contact 232 and fourth joining contact 312.

Furthermore, an implementation of the present application further provide a memory system. The memory system comprises a controller and the above-mentioned semiconductor package structure, wherein the controller is coupled to the semiconductor package structure and configured to control the semiconductor package structure to store data.

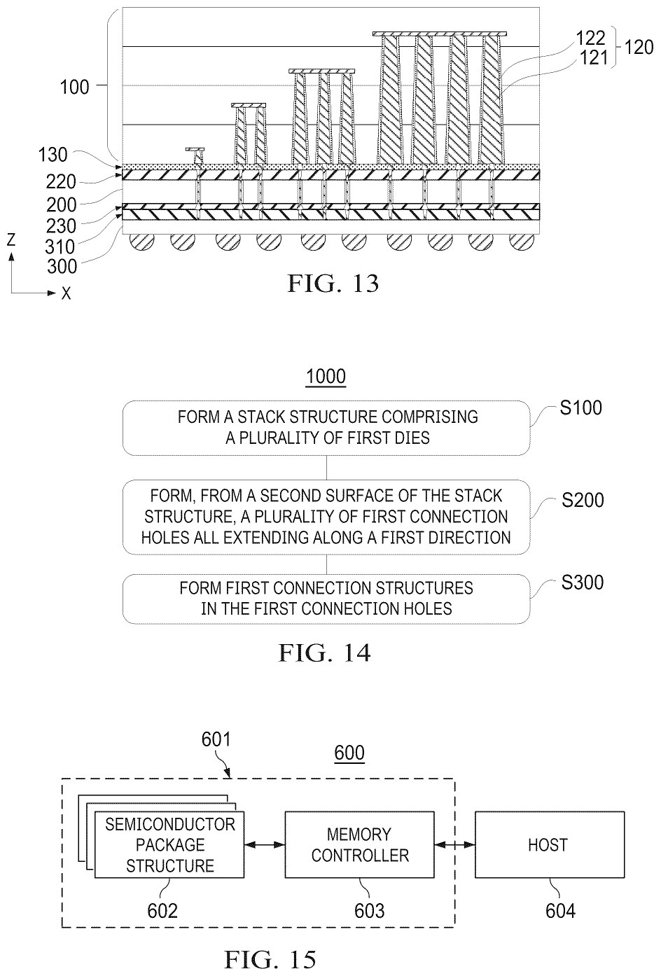

FIG. 15 shows a block diagram of a system having a semiconductor package structure according to an implementation of the present application. The system 600 may comprise a mobile phone, a desktop computer, a laptop computer, a tablet, a vehicle computer, a gaming console, a printer, a positioning device, a wearable electronic device, a smart sensor, a virtual reality (VR) device, an augmented reality (AR) device, or any other suitable electronic device having storage therein. As shown in FIG. 15, the system 600 may comprise a host 604 and a memory system 601, the memory system 601 is provided with one or semiconductor package structures 602 and a memory controller 603. The host 604 may be a processor of an electronic device, such as a central processing unit (CPU), or a system-on-chip (SoC), such as an application processor (AP). The host 604 may be configured to send or receive data to or from the semiconductor package structure 602.

The semiconductor package structure 602 may be any of semiconductor package structures disclosed in the present application, such as the semiconductor package structures shown in FIGS. 11 to 13. According to some implementations, the memory controller 603 is coupled to the semiconductor package structure 602 and the host 604, and is configured to control the semiconductor package structure 602. The memory controller 603 may manage data stored in the semiconductor package structure 602, and communicate with the host 604.

In some implementations, the memory controller 603 is designed for operating in a low duty-cycle environment like secure digital (SD) cards, compact flash (CF) cards, universal serial bus (USB) flash drives, or other media for use in electronic devices, such as personal computers, digital cameras, mobile phones, etc. In some implementations, the memory controller 603 is designed for operating in a high duty-cycle environment like solid state drives (SSDs) or embedded multimedia cards (eMMCs) used as data storage for mobile devices, such as smartphones, tablet computers, laptop computers, etc., and enterprise storage arrays. The memory controller 603 may be configured to control operations of the semiconductor package structure 602, such as read, erase, and program operations. The memory controller 603 may further be configured to manage various functions with respect to data stored or to be stored in the semiconductor package structure 602, including, but not limited to, bad-block management, garbage collection, logical-to-physical address translation, wear leveling, etc. In some implementations, the memory controller 603 is further configured to process error correction codes (ECCs) with respect to the data read from or written to the semiconductor package structure 602. The memory controller 603 may further perform any other suitable functions, for example, formatting the semiconductor package structure 602. The memory controller 603 may communicate with an external device (e.g., the host 604) according to a particular communication protocol. For example, the memory controller 603 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a firewire protocol, etc.

It is to be understood that, various forms of flows as shown above may be used, and operations may be reordered, added or deleted. As an example, as long as expected results of the technical solutions disclosed by the present application can be achieved, various operations set forth in the present disclosure may be performed in parallel, in sequence, or in a different order, and there is no limitation herein in this regard.

The above implementations do not constitute a limitation to the protection scope of the present application. Those skilled in the art should understand that various modifications, combinations, sub-combinations and substitutions can be made according to design requirements by equalizing other factors. Any modification, equivalent substitution and improvement and the like made within the spirit and principles of the present application shall be included in the protection scope of the present application.

What is claimed is:

1. A semiconductor package structure, comprising:
a stack structure comprising a plurality of first dies stacked sequentially along a first direction, wherein the stack structure has a first surface and a second surface opposite to each other along the first direction; and
a plurality of first connection structures extending along the first direction from the second surface and respectively connected to different ones of the first dies,
wherein:
numbers of the first connection structures connected to different ones of the first dies are different;
maximum sizes, along a second direction that intersects with the first direction, of the first connection structures connected to different ones of the first dies are different; or
a combination thereof.

2. The semiconductor package structure of claim 1, wherein one of two consecutive first dies is a first stack die, the other one is a second stack die, and the first stack die is located on a side of the second stack die along a direction from the second surface to the first surface,
wherein:
a number of the first connection structures connected to the first stack die is greater than a number of the first connection structures connected to the second stack die;
a maximum size, along the second direction, of the first connection structures connected to the first stack die is greater than a maximum size, along the second direction, of the first connection structures connected to the second stack die; or
a combination thereof.

3. The semiconductor package structure of claim 1, wherein at least one of the first connection structures comprises:
a first conductive structure extending along the first direction from the second surface and connected to a corresponding one of the first dies; and
a first isolation layer cladding a sidewall of the first conductive structure extending along the first direction.

4. The semiconductor package structure of claim 1, wherein the plurality of first connection structures respectively extend into different ones of the first dies along the first direction.

5. The semiconductor package structure of claim 1, wherein two consecutive first dies are connected through bonding.

6. The semiconductor package structure of claim 1, further comprising:
a second die located on a side of the stack structure along a direction from the first surface to the second surface; and
a plurality of second connection structures extending through the second die along the first direction and respectively connected to different ones of the first connection structures.

7. The semiconductor package structure of claim 6, further comprising:
a first joining layer located on a side of the stack structure facing toward the second die and connected to at least one of the first connection structures; and
a second joining layer located on a side of the second die facing toward the stack structure and connected to at least one of the second connection structures,
wherein the first joining layer is joined with the second joining layer.

8. The semiconductor package structure of claim 7, wherein the first joining layer comprises a first dielectric layer and a plurality of first joining contacts, and the plurality of first joining contacts extend through the first dielectric layer along the first direction and are respectively connected to different ones of the first connection structures;
wherein the second joining layer comprises a second dielectric layer and a plurality of second joining contacts, the plurality of second joining contacts extend through the second dielectric layer along the first direction and are respectively connected to different ones of the second connection structures, and the plurality of first joining contacts are respectively in contact with different ones of the second joining contacts.

9. The semiconductor package structure of claim 6, wherein at least one of the first dies comprises at least one of a memory die or a peripheral circuit, and the second die comprises a logic die.

10. The semiconductor package structure of claim 6, further comprising:
a substrate located on a side of the second die facing away from the stack structure, and connected to at least one of the second connection structures.

11. The semiconductor package structure of claim 10, further comprising:
a third joining layer located on a side of the second die facing away from the stack structure and connected to the second connection structure; and
a fourth joining layer located on a side of the substrate facing toward the second die and connected to the substrate,
wherein the third joining layer is joined with the fourth joining layer.

12. The semiconductor package structure of claim 11, wherein the third joining layer comprises a third dielectric layer and a plurality of third joining contacts, and the plurality of third joining contacts extend through the third dielectric layer along the first direction and are respectively connected to different ones of the second connection structures;
wherein the fourth joining layer comprises a fourth dielectric layer and a plurality of fourth joining contacts, the plurality of fourth joining contacts extend through the fourth dielectric layer along the first direction and are respectively connected to the substrate, and the plurality of third joining contacts are respectively in contact with different ones of the fourth joining contacts.

13. A manufacturing method of a semiconductor package structure, comprising:
forming a stack structure, wherein the stack structure comprises a plurality of first dies stacked sequentially along a first direction, and the stack structure has a first surface and a second surface opposite to each other along the first direction;
forming, from the second surface, a plurality of first connection holes extending along the first direction; and
forming first connection structures in the first connection holes, wherein a plurality of the first connection structures are respectively connected to different ones of the first dies;
wherein:
numbers of the first connection structures connected to different ones of the first dies are different,
maximum sizes, along a second direction that intersects with the first direction, of the first connection structures connected to different ones of the first dies are different; or
a combination thereof.

14. The manufacturing method of the semiconductor package structure of claim 13, wherein forming the stack structure comprises:
sequentially connecting the plurality of first dies along the first direction through bonding.

15. The manufacturing method of the semiconductor package structure of claim 13, wherein forming the first connection structures in the first connection holes comprises:
forming first isolation layers on sidewalls of the first connection holes extending along the first direction; and
forming first conductive structures in first pores surrounded by the first isolation layers,
wherein the first connection structure comprises the first isolation layer and the first conductive structure.

16. The manufacturing method of the semiconductor package structure of claim 13, further comprising:
forming a plurality of second connection structures in a second die, wherein the second connection structures extend through the second die along the first direction; and
joining the second die with the stack structure, wherein the second surface of the stack structure faces toward the second die, and the plurality of second connection structures are respectively connected to different ones of the first connection structures.

17. The manufacturing method of the semiconductor package structure of claim 16, wherein joining the second die with the stack structure comprises:
forming a first dielectric layer on the second surface of the stack structure;
forming a plurality of first joining contacts in the first dielectric layer, wherein the plurality of first joining contacts extend through the first dielectric layer along the first direction and are respectively connected to different ones of the first connection structures;
forming a second dielectric layer on a side of the second die;
forming a plurality of second joining contacts in the second dielectric layer, wherein the plurality of second joining contacts extend through the second dielectric layer along the first direction and are respectively connected to different ones of the second connection structures; and
joining the first dielectric layer with the second dielectric layer, wherein the plurality of first joining contacts are respectively in contact with different ones of the second joining contacts.

18. The manufacturing method of the semiconductor package structure of claim 16, further comprising:
joining a substrate with the second die, wherein the substrate and the stack structure are respectively located on two sides of the second die along the first direction.

19. The manufacturing method of the semiconductor package structure of claim 18, wherein joining the substrate with the second die comprises:
forming a third dielectric layer on a side of the second die;
forming a plurality of third joining contacts in the third dielectric layer, wherein the plurality of third joining contacts extend through the third dielectric layer along the first direction and are respectively connected to different ones of the second connection structures;
forming a fourth dielectric layer on a side of the substrate;
forming a plurality of fourth joining contacts in the fourth dielectric layer, wherein the plurality of fourth joining contacts extend through the fourth dielectric layer along the first direction and are connected to the substrate; and
joining the third dielectric layer with the fourth dielectric layer, wherein the plurality of third joining contacts are respectively in contact with different ones of the fourth joining contacts.

20. A memory system, comprising:
a semiconductor package structure comprising:
a stack structure comprising a plurality of first dies stacked sequentially along a first direction, wherein the stack structure has a first surface and a second surface arranged opposite to each other along the first direction; and
a plurality of first connection structures extending along the first direction from the second surface and respectively connected to different ones of the first dies,
wherein:
numbers of the first connection structures connected to different ones of the first dies are different;
maximum sizes, along a second direction intersecting the first direction, of the first connection structures connected to different ones of the first dies are different; or
a combination thereof; and
a controller coupled to the semiconductor package structure and configured to control the semiconductor package structure to store data.
